(19) United States
(12) Patent Application Publication
(10) Pub. No.: US 2025/0316515 A1
(43) Pub. Date: Oct. 9, 2025

(54) ARTICLE TRANSFER AND STORAGE APPARATUS

(71) Applicant: Samsung Electronics Co., Ltd., Suwon-si (KR)

(72) Inventors: Hyoengrak Kim, Suwon-si (KR); Seunggyu Kang, Suwon-si (KR); Sangmin Kim, Suwon-si (KR); Youngwook Kim, Suwon-si (KR); Soyoung Baek, Suwon-si (KR); Jaesung Byun, Suwon-si (KR); Yongjun Ahn, Suwon-si (KR); Hyunwoo Lee, Suwon-si (KR); Jeonghun Lim, Suwon-si (KR); Junhyuk Chang, Suwon-si (KR)

(21) Appl. No.: 19/019,694

(22) Filed: Jan. 14, 2025

(30) Foreign Application Priority Data
Apr. 8, 2024 (KR) 10-2024-0047465

(51) Int. Cl. H01L 21/677; B65G 47/90; H01F 7/20; H01L 21/67

(52) U.S. Cl. CPC H01L 21/67769; B65G 47/90; H01L 21/67294; H01L 21/67766; H01F 7/20

(57) ABSTRACT

An article transfer and storage apparatus includes a case installed in a semiconductor factory and including a frame, the frame including at least a first shelf plate extending in a first horizontal direction, and a plurality of storage ports arranged on the first shelf plate and configured to accommodate a semiconductor carrier, and a storage port transport configured to move the storage ports in the first horizontal direction, and a transfer robot including a transport base at a bottom of the transfer robot, the transfer robot configured to place the semiconductor carrier in the case or take out the semiconductor carrier from the case and move the semiconductor carrier.

### CROSS-REFERENCE TO RELATED APPLICATION

This application is based on and claims priority under 35 U.S.C. § 119 to Korean Patent Application No. 10-2024-0047465, filed on Apr. 8, 2024, in the Korean Intellectual Property Office, the disclosure of which is incorporated by reference herein in its entirety.

### BACKGROUND

Aspects of the inventive concept relate to an article transfer and storage apparatus, and more particularly, to an article transfer and storage apparatus including a transfer robot.

In general, semiconductor devices may be manufactured through several processes. The manufacturing processes, such as exposure, deposition, and etching, may be performed on semiconductor substrates. To perform various processes, it may be necessary to move semiconductor devices to different equipment. The semiconductor devices may be transported through an automated guided vehicle (AGV) or overhead hoist transfer (OHT). In addition, for work efficiency, the semiconductor substrates may be transported into a storage device for storage or may be taken out while stored in the storage device. Research into efficient transfer and storage of semiconductor substrates is ongoing.

### SUMMARY

Aspects of the inventive concept provide an article transfer and storage apparatus that has the improved throughput of transferring and storing semiconductor carriers in a semiconductor processing line and maintains the system operation in the event of a breakdown.

In addition, the inventive concept is not limited to that mentioned above and other aspects of the inventive concept not mentioned above may be clearly understood by those skilled in the art from the description below.

According to an aspect of the inventive concept, an article transfer and storage apparatus includes a case installed in a semiconductor factory and comprising: a frame, the frame including at least a first shelf plate extending in a first horizontal direction, and a plurality of storage ports arranged on the first shelf plate, each of the plurality of storage ports configured to accommodate a semiconductor carrier, and a storage port transport configured to move the storage ports in the first horizontal direction; and a transfer robot comprising a transport base at a bottom of the transfer robot, and the transfer robot configured to place the semiconductor carrier in the case or take out the semiconductor carrier from the case and move the semiconductor carrier.

According to another aspect of the inventive concept, an article transfer and storage apparatus includes a case installed in a semiconductor factory and comprising: a frame, the frame including at least a first shelf plate extending in a first horizontal direction, and a plurality of storage ports arranged on the first shelf plate, each of the plurality of storage ports configured to accommodate a semiconductor carrier, and a storage port transport configured to move the storage ports in the first horizontal direction; and a transfer robot comprising a transport base at a bottom of the transfer robot, and the transfer robot configured to place the semiconductor carrier in the case or take out the semiconductor carrier from the case and move the semiconductor carrier, wherein the first shelf plate of the case includes two rows arranged in a second horizontal direction perpendicular to the first horizontal direction.

According to another aspect of the inventive concept, an article transfer and storage apparatus includes a case installed in a semiconductor factory and comprising: a frame, the frame including at least a first shelf plate extending in a first horizontal direction, and a plurality of storage ports arranged on the first shelf plate, each of the plurality of storage ports configured to accommodate a semiconductor carrier, and a storage port transport configured to move the storage ports in the first horizontal direction; and a transfer robot comprising: a transport base at a bottom of the transfer robot, a gripper configured to grip the semiconductor carrier, an extendable arm configured to move the gripper in a horizontal direction, a lift configured to move the extendable arm in a vertical direction, and a transfer shelf configured to support the semiconductor carrier, wherein the transfer robot is configured to place the semiconductor carrier in the case or take out the semiconductor carrier from the case and move the semiconductor carrier, wherein the first shelf plate of the case includes a plurality of floors spaced apart in the vertical direction and further includes two rows arranged in a second horizontal direction perpendicular to the first horizontal direction, each floor of the plurality of floors of the first shelf plate comprising a spare space corresponding to a size of at least one of the plurality of storage ports, wherein the storage port transport comprises: a guide rail fixed to the frame, the guide rail extending in the first horizontal direction; a rail coupler attached to each of the storage ports and configured to move along the guide rail; and a port driver comprising an electromagnet disposed at a first end of a corresponding storage port of the plurality of storage ports, a magnetic material disposed at a second end of each storage port of the plurality of storage ports opposite to the first end, and a damper coupled to one side of the magnetic material disposed at the second end of each storage port, wherein the port driver is configured to provide a driving force to move the plurality of storage ports in the first horizontal direction, wherein the case comprises: a wheel that allows the case to move; and an identification device configured to recognize an ID of the semiconductor carrier transferred from the transfer robot, wherein the extendable arm of the transfer robot is configured to extend, wherein the gripper is configured to grip the semiconductor carrier placed in a first row of the two rows of the first shelf plate located farther away from the transfer robot in the second horizontal direction than a second row of the two rows of the first shelf plate while the extendable arm is in an extended position, and wherein the article transfer and storage apparatus further comprises a controller configured to move the plurality of storage ports and control the transfer robot to place the semiconductor carrier in the case or to take out the semiconductor carrier from the case.

### BRIEF DESCRIPTION OF THE DRAWINGS

Embodiments will be more clearly understood from the following detailed description taken in conjunction with the accompanying drawings in which:

FIG. 1 is a perspective view of an article transfer and storage apparatus according to an embodiment;

FIG. 2 is a front view of an article transfer and storage apparatus according to an embodiment;

FIG. 3 is a front view of a shelf structure according to an embodiment;

FIG. 4 is a perspective view illustrating a storage port moving unit according to an embodiment;

FIG. 5 is a perspective view illustrating a storage port moving unit according to an embodiment;

FIG. 6 is a schematic front view of a transfer robot according to an embodiment;

FIG. 7 is a diagram illustrating a slider module, a rotation module, and a lifting module of a transfer robot according to an embodiment;

FIG. 8 is a diagram illustrating an operating method of a rotation module and a lifting module of a transfer robot according to an embodiment;

FIG. 9 is a diagram illustrating a process by which a transfer robot takes out a semiconductor carrier located in a back row, according to an embodiment;

FIG. 10 is a diagram illustrating a process by which a transfer robot takes out a semiconductor carrier located in a back row, according to an embodiment; and

FIG. 11 is a diagram showing a path along which a transfer robot moves within a semiconductor device manufacturing plant, according to an embodiment.

### DETAILED DESCRIPTION OF THE EMBODIMENTS

Hereinafter, embodiments are described in detail with reference to the attached drawings. The same reference numerals are used for the same components in the drawings and duplicate descriptions thereof are omitted.

In this specification, a vertical direction may be defined as a Z direction, and each of a first horizontal direction and a second horizontal direction may be defined as a direction perpendicular to the Z direction. The first horizontal direction may be referred to as an X direction and the second horizontal direction may be referred to as a Y direction. A vertical level may refer to a height level in the vertical direction (Z direction). A horizontal transfer may refer to a transfer in the horizontal direction (X direction and/or Y direction) and a vertical transfer may refer to a transfer in the vertical direction (Z direction).

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

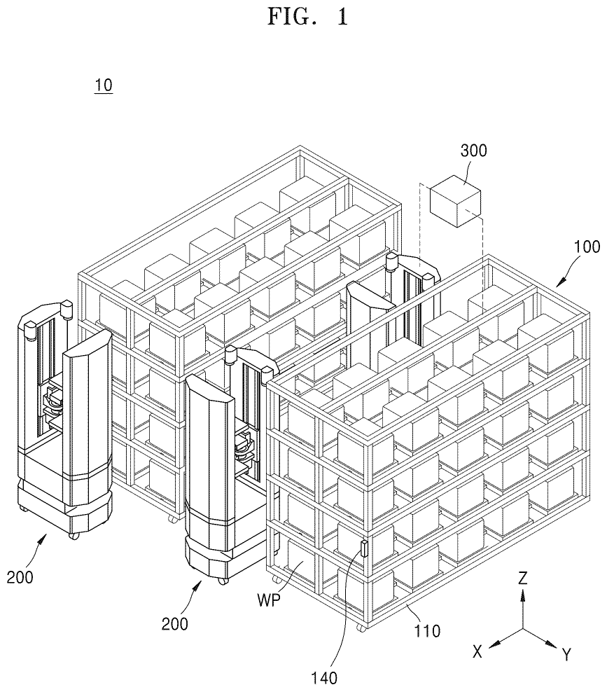

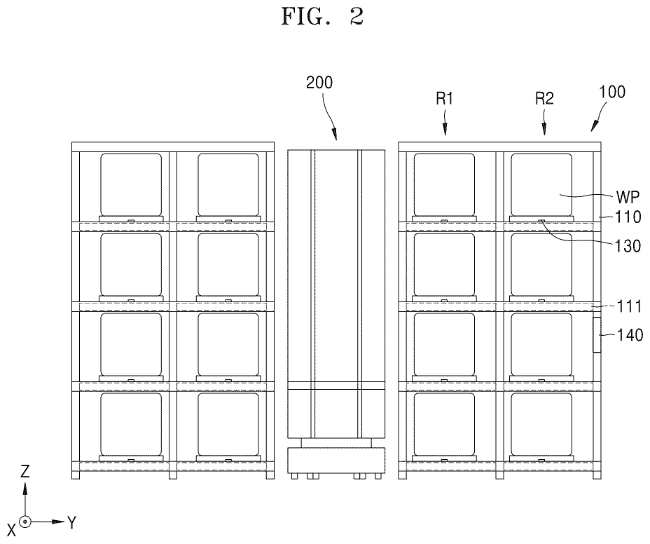

FIG. 1 is a perspective view of an article transfer and storage apparatus according to an embodiment. FIG. 2 is a front view of an article transfer and storage apparatus according to an embodiment.

Referring to FIGS. 1 and 2, the article transfer and storage apparatus 10 according to an embodiment may include a shelf structure 100 (e.g., a case) that stores semiconductor carriers WP and a transfer robot 200 that transfers the semiconductor carriers WP.

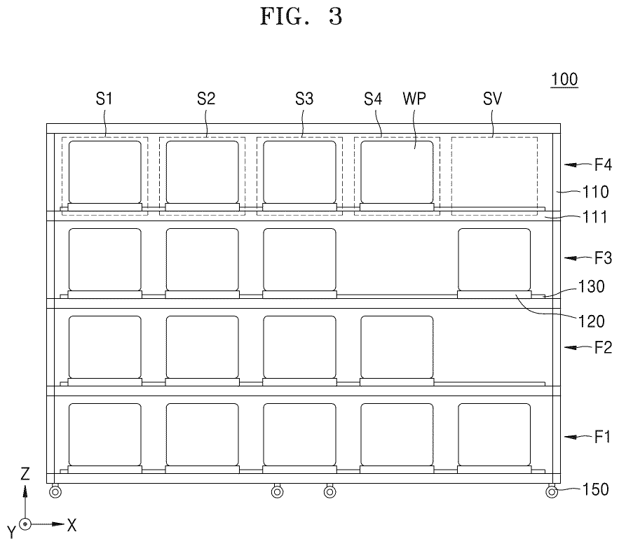

The shelf structure 100 which is a structure installed in a semiconductor device manufacturing plant may store the semiconductor carriers WP. The shelf structure 100 may include a plurality of floors in the vertical direction (Z direction) and may be configured to store a plurality of semiconductor carriers WP on each floor. The configuration of the shelf structure 100 is described below with reference to FIGS. 3 to 5.

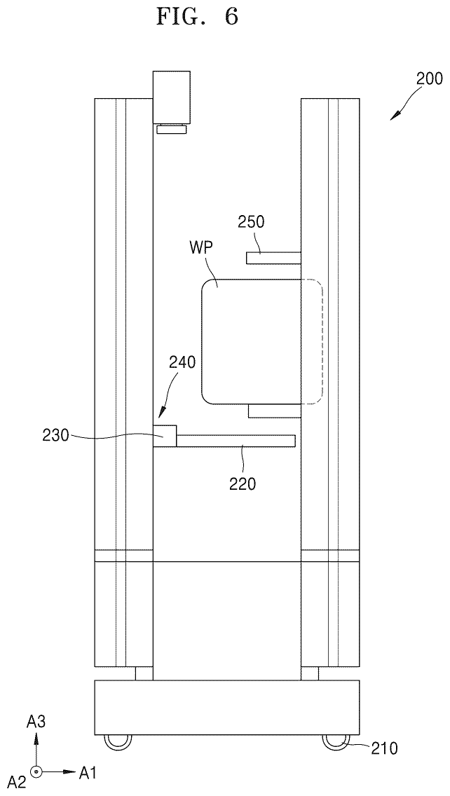

The transfer robot 200 may move within the semiconductor device manufacturing plant and transport the semiconductor carriers WP. The transfer robot 200 may be configured to move along the floor within the semiconductor device manufacturing plant. According to an embodiment, the semiconductor carriers WP may be taken into the shelf structure 100 (e.g., placed in the shelf structure 100) by the transfer robot 200 or the semiconductor carriers WP stored in the shelf structure 100 may be taken out by the transfer robot 200. The configuration of the transfer robot 200 is described below with reference to FIGS. 6 to 8.

The semiconductor carrier WP may be configured to hold wafers. The semiconductor carrier WP may include a container that stores semiconductor substrates, such as wafers. The semiconductor carrier WP may include a sealed container to protect the substrates from atmospheric foreign substances or chemical contamination.

The semiconductor carrier WP may include a body with an open space on one side and a door that opens and closes the open space. The inner wall of the body may be provided with a plurality of slots into which a portion of an edge of the semiconductor substrate is inserted. The slots may be provided on the inner wall of the body while being spaced apart at certain intervals in the vertical direction (Z direction). The body may include a material and/or a structure optimized for extreme cleanliness. A flat spring may be installed on the inner wall of the door to apply a certain pressure to the substrates stored in the semiconductor carrier WP when the door is closed.

In some embodiments, the semiconductor carrier WP may include a front opening unified pod (FOUP) or a cassette. In addition, in some embodiments, the semiconductor carrier WP may include a magazine configured to accommodate a plurality of semiconductor substrates and a tray configured to accommodate a plurality of semiconductor substrates. However, the semiconductor carrier WP is not limited to thereto and can be any container for storing articles.

According to some embodiments, the article transfer and storage apparatus 10 may further include a controller 300. The controller 300 may communicate with the shelf structure 100 and the transfer robot 200 and may control the shelf structure 100 and the transfer robot 200. For example, the controller 300 may receive information about the location of the semiconductor carriers WP stored in the shelf structure 100 to control the movement path of the transfer robot 200. In addition, the controller 300 may be configured to control the transfer robot 200 to move the position of a storage port 120 (see FIG. 3) arranged on the shelf structure 100 so that a target semiconductor carrier WP can be taken out but is not limited thereto.

The controller 300 may include a memory device, such as read-only memory (ROM) and random-access memory (RAM), in which various programming instructions are stored, and a processor, such as a microprocessor, a central processing unit (CPU), and a graphics processing unit (GPU), configured to process programming instructions stored in the memory device and externally provided signals. In addition, the controller 300 may include a receiver and a transmitter for receiving and transmitting electrical signals. The controller 300 may be controlled by software on a tangible computer-readable medium and that includes the above-mentioned programming instructions, and some of the control instructions may be set or controlled by a technician using a user interface such as input/output devices such as a display screen, keyboard, etc.

The article transfer and storage apparatus 10 may include a plurality of shelf structures 100 and a plurality of transfer robots 200. In FIG. 1, only one transfer robot 200 and one shelf structure 100 are shown as communicating with the controller 300, but this is for the sake of simplifying the drawing. All the shelf structures 100 and transfer robots 200 in the semiconductor device manufacturing plant may communicate with the controller 300.

FIG. 3 is a front view of a shelf structure according to an embodiment.

Referring to FIGS. 1 to 3, the shelf structure 100 may include a frame 110 including a shelf plate 111, a storage port 120, a storage port moving unit 130, an ID identification device 140 (e.g., an identification device, see FIGS. 1 and 2), and a wheel 150.

The frame 110 which forms the frame of the shelf structure 100 may include a portion extending in the vertical direction (Z direction), a portion extending in the first horizontal direction (X direction), and a portion extending in the second horizontal direction (Y direction).

The shelf plate 111, which forms a shelf of the shelf structure 100, and which includes the portion extending in the first horizontal direction (X direction), may support the semiconductor carrier WP using the storage port 120. According to some embodiments, a plurality of storage ports 120 may be arranged on the shelf plate 111 in the first horizontal direction (X direction).

The shelf plate 111 may be formed in multiple floors (e.g., vertical levels) so as to overlap in the vertical direction (Z direction). That is, the frame 110 may include a plurality of shelf plates 111, wherein the shelf plates 111 may be spaced apart from each other in the vertical direction (Z direction). Referring to FIG. 3, the frame 110 of the shelf structure 100 includes the shelf plates 111 of the first floor F1, the second floor F2, the third floor F3, and the fourth floor F4, which are spaced apart from each other in the vertical direction (Z direction) but is not limited thereto. The frame 110 of the shelf structure 100 may include the shelf plates 111 of a plurality of floors.

In addition, a plurality of rows of shelf plates 111 may be formed in the frame 110 to overlap in the second horizontal direction (Y direction). For example, referring to FIG. 2, the frame 110 of the shelf structure 100 may include shelf plates 111 in a first row R1 and a second row R2 spaced apart from each other in the second horizontal direction (Y direction).

The storage port 120 (e.g., storage plate or tray) may be placed on the shelf plate 111 and may be configured to accommodate the semiconductor carrier WP. For example, the semiconductor carrier WP may be seated on the storage port 120. The storage port 120 may have a plate shape that supports the semiconductor carrier WP, but the shape of the storage port 120 is not limited thereto. Although not shown, the storage port 120 may include a separate structure that can be combined with the semiconductor carrier WP. For example, the storage port 120 may include a protrusion and/or a clamp structure that can be coupled to the bottom and/or side of the semiconductor carrier WP. However, the separate structure included in the storage port 120 is not limited thereto and may include other structures for supporting the semiconductor carrier WP.

A plurality of storage ports 120 may be provided on each shelf plate 111. The plurality of storage ports 120 may be arranged in the first horizontal direction (X direction). For example, the storage ports 120 may be arranged in a plurality of sections in the first horizontal direction (X direction). According to some embodiments, a spare space SV corresponding to the size of at least one storage port 120 may be provided on the shelf plate 111. The spare space SV may provide a space where the storage port 120 can move in the first horizontal direction (X direction).

For example, referring to FIG. 3, the shelf plate 111 corresponding to the fourth floor F4 may include a first section S1, a second section S2, a third section S3, a fourth section S4, and the spare space SV. Each of the first section S1, the second section S2, the third section S3, the fourth section S4, and the spare space SV may have a size that enables a semiconductor carrier WP to be accommodated therein, and may each correspond to a respective storage port 120. The storage ports 120 accommodating the semiconductor carriers WP are arranged in the first section S1, the second section S2, the third section S3, and the fourth section S4 in the horizontal direction (X direction) on the shelf plate 111 of the fourth floor F4 and the shelf plate 111 includes the spare space SV where a storage port 120 is not arranged. As the spare space SV where the storage port 120 is not arranged is included in the shelf plate 111, at least one of the storage ports 120 in the first section S1, the second section S2, the third section S3, and the fourth section S4 may be moved in the first horizontal direction (X direction).

The storage port moving unit 130, also described as the storage port transport, may be configured to move the storage port 120 on the shelf plate 111 in the first horizontal direction (X direction).

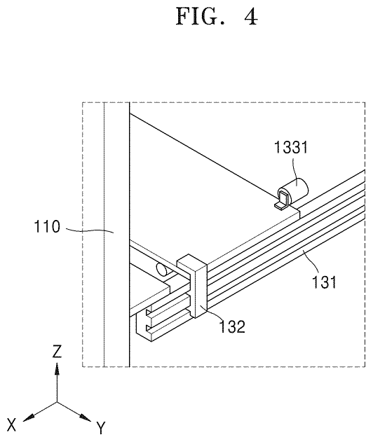

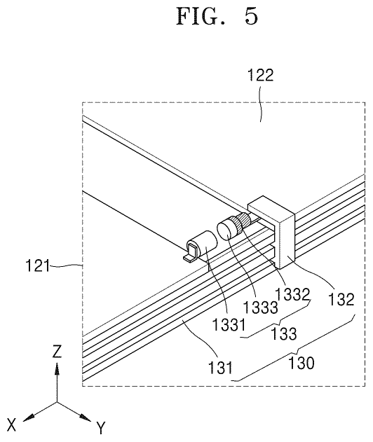

FIGS. 4 and 5 are perspective views illustrating the storage port moving unit 130 according to an embodiment.

Referring to FIGS. 3 to 5, the storage port moving unit 130 may include a guide rail 131, a rail coupling unit 132, and a port driving unit 133.

The guide rail 131 may extend in the first horizontal direction (X direction) and may be fixed to the frame 110.

A rail coupling unit 132, or rail coupler may be attached to each storage port 120 and coupled to the guide rail 131. The rail coupling unit 132 may be a rail connector such as a brace or bracket that may move in the first horizontal direction (X direction) along the guide rail 131 while being coupled to the guide rail 131.

The port driving unit 133 may be a port driver that provides a driving force to move the storage port 120 in the first horizontal direction (X direction). According to some embodiments, the port driving unit 133 may be a magnetic actuator and may include an electromagnet 1331, a magnetic material 1332, and a damper 1333. For example, the electromagnet 1331 may be placed at one end of the storage port 120 and the magnetic material 1332 may be placed at the other end thereof. Referring to FIG. 5, a first storage port 121 and a second storage port 122 adjacent to each other in the first horizontal direction (X direction) may be arranged so that the electromagnet 1331 placed at one end of the first storage port 121 faces the magnetic material 1332 placed at the other end of the second storage port 122. Thus, due to the magnetism of the electromagnet 1331 placed on the first storage port 121, the magnetic material 1332 placed on the second storage port 122 may be moved, thereby moving the second storage port 122. The magnetism of the electromagnet 1331 may be controlled, for example, by the controller 300. For example, in a first configuration, a first current may be applied to the electromagnet 1331 placed at the one end of the first storage port 121 to attract the magnetic material 1332 placed at the other end of the second storage port 122 to cause the second storage port 122 to move toward the first storage port 121. In a second configuration, a second current (or no current) may be applied to the electromagnet 1331 placed at the one end of the first storage port 121 so as not to attract the magnetic material 1332 placed at the other end of the second storage port 122 to cause the second storage port 122 to be movable away from the first storage port 121. The damper 1333 may be coupled to one side of the magnetic material 1332. By placing the damper 1333 on one side of the magnetic material 1332, collision caused by the movement of the first storage port 121 and the second storage port 122 which are adjacent to each other may be prevented.

The port driving unit 133 is not limited to the above-mentioned configuration and may include other configurations capable of providing a driving force to move the storage port 120 in the first horizontal direction (X direction). The port driving unit 133 may be controlled by the controller 300. For example, the controller 300 may switch on or off the electromagnet 1331 to move the storage port 120.

Referring to FIGS. 1 and 2, the shelf structure 100 may further include an ID identification device 140 (e.g., an identification device 140). The ID identification device 140 may identify the ID of the semiconductor carrier WP to be taken into the shelf structure 100. For example, the ID identification device 140 may include a tag reader. The ID of the semiconductor carrier WP may be provided in the form of an identification tag, wherein the identification tag may include a radio frequency identification (RFID) tag, a QR code, or a barcode, but is not limited thereto. The ID identification device 140 may recognize the identification tag of the semiconductor carrier WP and confirm information about the semiconductor carrier WP and the location where the semiconductor carrier WP is taken and stored. According to an embodiment, the ID identification device 140 may be configured to communicate with the controller 300. For example, the ID identification device 140 may include a camera, an RFID receiver, an RFID transceiver, or a barcode scanner.

Referring to FIG. 3, the shelf structure 100 may include a wheel 150 (e.g., a plurality of wheels). The wheel 150 is arranged at the bottom of the shelf structure 100 and is configured to move the shelf structure 100.

FIG. 6 is a schematic front view of a transfer robot according to an embodiment.

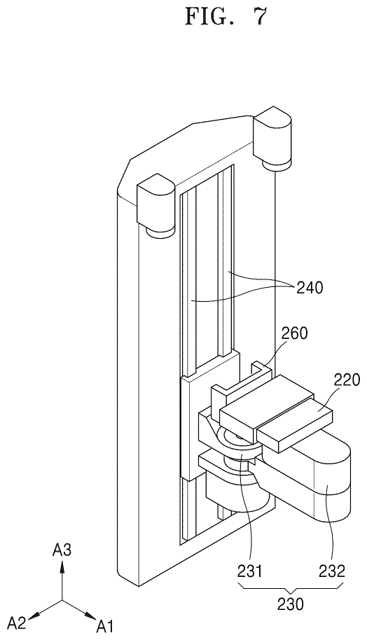

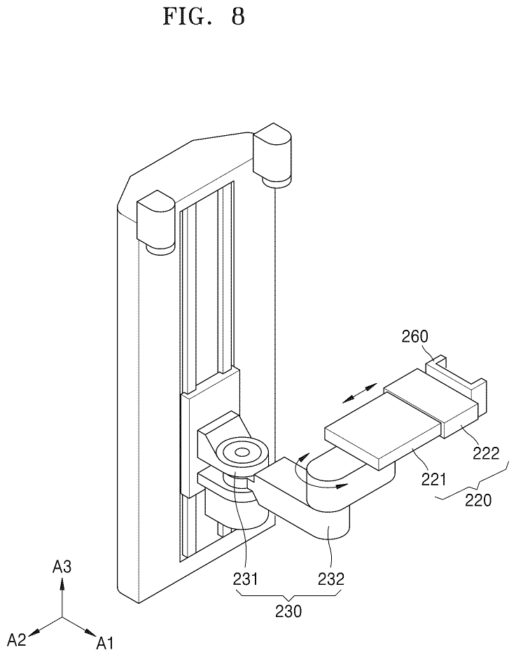

FIG. 7 is a diagram illustrating a slider module, a rotation module, and a lifting module of a transfer robot according to an embodiment and FIG. 8 is a diagram illustrating an operating method of a rotation module and a lifting module of a transfer robot according to an embodiment.

Referring to FIGS. 6 to 8, the transfer robot 200 may include a traveling module 210, a slider module 220 (e.g., an extendable arm), a rotation module 230 (e.g., a rotator), a lifting module 240 (e.g., a lift), a shelf module 250 (e.g., a transfer shelf), and a gripper 260. The transfer robot 200 may move within the semiconductor device manufacturing plant and may transfer and store the semiconductor carriers WP into the shelf structure 100 or take out the semiconductor carriers WP stored in the shelf structure 100.

The traveling module 210 may be a transport base that allows the transfer robot 200 to move along the floor of the semiconductor device manufacturing plant. According to some embodiments, the traveling module 210 may include a wheel (e.g., a plurality of wheels). For example, the traveling module 210 may include an automated guided vehicle (AGV) and/or an autonomous mobile robot (AMR). For example, the traveling module 210 may move along a QR code or series of QR codes attached to the floor of the semiconductor device manufacturing plant or move by detecting the surroundings, including the shelf structure 100, using sensors and laser scanners, to construct a site map and creating an optimal path. However, the traveling method of the traveling module 210 is not limited thereto. For example, the traveling module 210 may be controlled by the controller 300.

When storing or taking out the semiconductor carrier WP, the slider module 220, the rotation module 230, the lifting module 240, and the gripper 260 may adjust the position of the transfer robot 200 to approach and grip the semiconductor carrier WP or place the semiconductor carrier WP at the target location.

The gripper 260 may be connected to one side of the slider module 220, wherein the slider module 220 may move the gripper 260 in a horizontal direction. The horizontal direction may be perpendicular to a vertical direction (A3 direction) of the transfer robot 200. To this end, the slider module 220 may increase or decrease in length in the horizontal direction. The rotation module 230 may be connected to the other side of the slider module 220.

For example, the slider module 220 may include a first portion 221 and a second portion 222. When the transfer robot 200 intends to grip the semiconductor carrier WP located far away, the second portion 222 of the slider module 220 may extend from the first portion 221 thereof. Conversely, in the traveling mode of the transfer robot 200, the first portion 221 may overlap the second portion 222 to minimize the length of the slider module 220. For example, the slider module 220 may be controlled by the controller 300.

The rotation module 230 may rotate the slider module 220 to which the gripper 260 is connected in the horizontal direction. The rotation module 230 may rotate the slider module 220 about a vertical axis extending in the vertical direction (A3 direction). For example, the rotation module 230 may include a first rotator 231 located on a side connected to the lifting module 240 and a second rotator 232 located on a side connected to the slider module 220. For example, when the transfer robot 200 intends to grip the semiconductor carrier WP, the rotation module 230 may be rotated so that the slider module 220 and the gripper 260 are aligned to face the semiconductor carrier WP. Each rotator may include an actuator or motor configured to rotate the different components with respect to each other. For example, the rotation module 230 may be controlled by the controller 300.

The lifting module 240 may be connected to the rotation module 230 and the slider module 220 and may move the rotation module 230 and the slider module 220 in the vertical direction (A3 direction). According to some embodiments, by moving the slider module 220 and the rotation module 230 in the vertical direction (A3 direction), the lifting module 240 may control the positioning of the slider module 220 and the gripper 260 at the vertical level where the semiconductor carrier WP is located. For example, the lifting module 240 may include a motor and/or an actuator configured to move the slider module 220, the rotation module 230, and the gripper 260 in the vertical direction (A3 direction). The motor and/or actuator may be connected to one or more cables, chains, wheels, cogs, pully systems, and/or hydraulic systems to cause the lifting module 240 to move in the vertical direction (A3 direction). For example, the lifting module 240 may be controlled by the controller 300.

The gripper 260 may be placed at one end of the slider module 220. The gripper 260 may grip the semiconductor carrier WP. The gripper 260 may include various configurations for gripping the semiconductor carrier WP. For example, the gripper 260 may be a gripping hand that includes a clamp structure (e.g., a clamp) for gripping the semiconductor carrier WP. Alternatively, the gripper 260 may grip the semiconductor carrier WP using an electromagnetic force.

The gripper 260 may be configured to switch between a grip posture that grips the semiconductor carrier WP and an un-grip posture that releases the grip on the semiconductor carrier WP. The gripper 260 may switch from the un-grip posture to the grip posture to take out the semiconductor carrier WP from the shelf structure 100 and may switch from the grip posture to the un-grip posture to store the semiconductor carrier WP on the shelf module 250 of the transfer robot 200. For example, the gripper 260 may be controlled by the controller 300.

The shelf module 250 may support the semiconductor carrier WP. Referring to FIG. 6, the transfer robot 200 may include a plurality of shelf modules 250. According to some embodiments, the shelf modules 250 may be placed facing the lifting module 240. For example, the plurality of shelf modules 250 may be arranged on the main body of the transfer robot 200 so as to face the lifting module 240 and be spaced apart in the vertical direction (A3 direction).

The shelf module 250 may provide a space to temporarily store the semiconductor carrier WP when the transfer robot 200 transports the semiconductor carrier WP. Therefore, one transfer robot 200 may transport multiple semiconductor carriers WP at the same time.

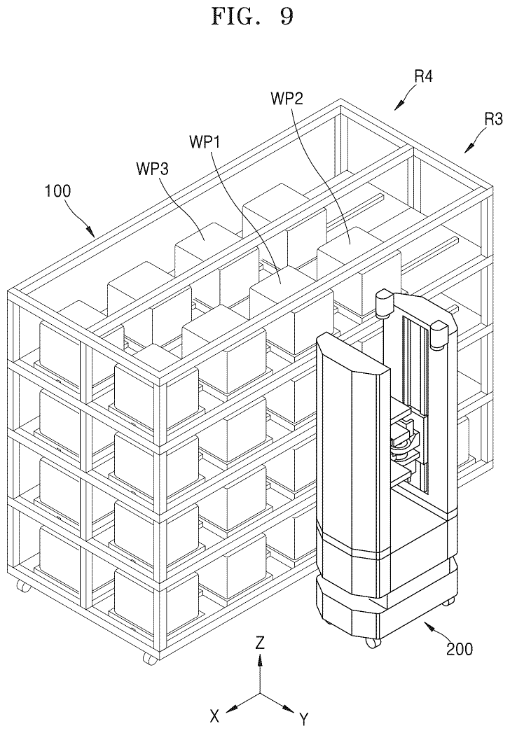

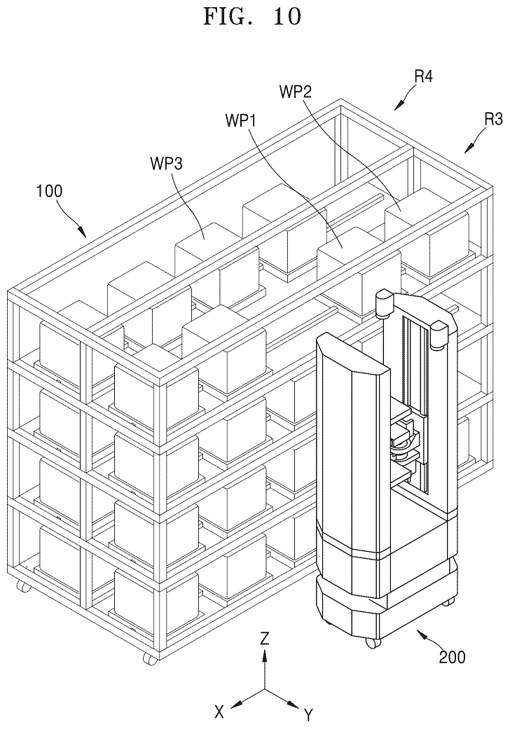

FIGS. 9 and 10 are diagrams illustrating a process by which a transfer robot 200 takes out a semiconductor carrier WP located in a back row of a shelf structure 100, according to an embodiment.

Referring to FIGS. 1, 3, 9 and 10, to take out a third semiconductor carrier WP3 in a second row R4 that is farther from the transfer robot 200 than the first row R3 is, a first semiconductor carrier WP1 located in a first row R3 overlapping the third semiconductor carrier WP3 in the second horizontal direction (Y direction) must be moved so as not to overlap with the third semiconductor carrier WP3 in the second horizontal direction (Y direction). According to an embodiment, the storage port moving unit 130 of the shelf structure 100 may move the first semiconductor carrier WP1 and the second semiconductor carrier WP2 located in the first row R3 in the first horizontal direction (X direction). For example, the storage port moving unit 130 may move the second semiconductor carrier WP2 in the X direction as shown in FIG. 9 into the spare space SV (see, e.g., FIG. 3). The storage port moving unit 130 may then move the first semiconductor carrier WP1 in the X direction to the space vacated by movement of the second semiconductor carrier WP2. However, embodiments are not limited thereto, and the storage port moving unit 130 may move the first and second semiconductor carriers WP1 and WP2 simultaneously. The transfer robot 200 may access the third semiconductor carrier WP3 located in the second row R4 using the lifting module 240, the rotation module 230, the slider module 220, and the gripper 260. According to some embodiments, the slider module 220 may extend across the first row R3 to grip the third semiconductor carrier WP3 located in the second row R4.

The controller 300 may receive information about the location of the third semiconductor carrier WP3 from the shelf structure 100 so that the transfer robot 200 can grip the target third semiconductor carrier WP3. In addition, the controller 300 may transmit the corresponding information to the traveling module 210 of the transfer robot 200 so that the transfer robot 200 moves to the location where the target third semiconductor carrier WP3 is stored. The controller 300 may control the storage port moving unit 130 of the shelf structure 100 to move the first semiconductor carrier WP1 and the second semiconductor carrier WP2 and access the third semiconductor carrier WP3.

The controller 300 may be a computer (or several interconnected computers) and may include, for example, one or more processors configured by software, such as a CPU (Central Processing Unit), GPU (graphics processor), controller, etc., and may include various functional modules of the computer. The computer may be a general purpose computer or may be dedicated hardware or firmware (e.g., an electronic or optical circuit, such as application-specific hardware, such as, for example, a digital signal processor (DSP) or a field-programmable gate array (FPGA)). A computer may be configured from several interconnected computers. Each functional module (or unit) may comprise a separate computer, or some or all of the functional module (or unit) may be comprised of and share the hardware of the same computer. Connections and interactions between the units described herein may be hardwired and/or in the form of data (e.g., as data stored in and retrieved from memory of the computer, such as a register, buffer, cache, storage drive, etc., such as part of an application programming interface (API)). The functional modules (or units) of the controller 300 may each correspond to a separate segment or segments of software (e.g., a subroutine) which configure the computer of the controller 300, and/or may correspond to segment(s) of software that also correspond to one or more other functional modules or units (e.g., the functional modules (or units) may share certain segment(s) of software or be embodied by the same segment(s) of software). As is understood, “software” refers to prescribed rules to operate a computer, such as code or script.

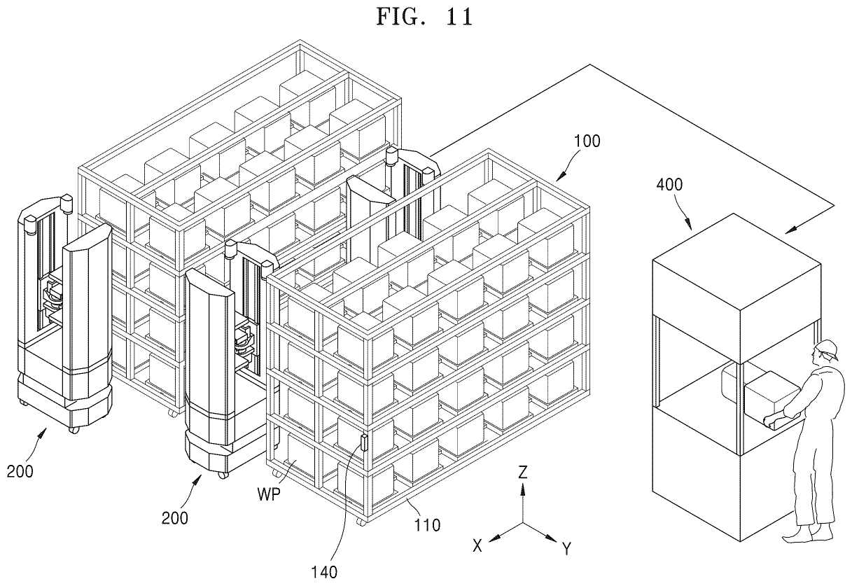

FIG. 11 is a diagram showing a path along which a transfer robot moves within a semiconductor device manufacturing plant, according to an embodiment.

The transfer robot 200 may transfer the semiconductor carrier WP between the shelf structure 100 and the equipment 400 installed in the semiconductor device manufacturing plant.

The equipment 400 may include production equipment configured to perform a semiconductor process on wafers or may include stockers on which the semiconductor carriers WP are stored. For example, the equipment 400 may include equipment configured to perform a diffusion process, a photolithography process, an etching process, a deposition process, a metallization process, an ion implantation process, a cleaning process, a polishing process and/or a packaging process for wafers. The equipment 400 may each include a load port on which the semiconductor carrier WP may be mounted.

The transfer robot 200 may receive information about the target location from the controller 300 and move to the target location based on the information transmitted from the controller 300. The target location may include a location of the storage port 120 or the equipment 400 within the shelf structure 100 where the semiconductor carrier WP to be taken out is stored.

The article transfer and storage apparatus 10 according to an embodiment may transfer the semiconductor carriers WP using the transfer robot 200 to store the semiconductor carriers WP on the shelf structure 100 or take out the semiconductor carriers WP from the shelf structure 100. The transfer robot 200 according to an embodiment may access the shelf structure 100 to simultaneously transfer a plurality of semiconductor carriers WP. The transfer throughput of the semiconductor carriers WP may be increased by using a plurality of transfer robots 200. The shelf structure 100, according to an embodiment, may be configured so that the storage port 120 supporting the semiconductor carrier WP can move in the longitudinal direction of the shelf plate 111. Thus, the semiconductor carrier WP may not overlap with surrounding semiconductor carriers WP when the transfer robot 200 takes out the semiconductor carrier WP or places the semiconductor carrier WP in the storage port 120. The article transfer and storage apparatus 10 according to an embodiment may use other transfer robots 200 when the transfer robot 200 breaks down because the transfer robot 200 is configured as a separate structure from the shelf structure 100, allowing the semiconductor device manufacturing process to proceed without delay.

While the inventive concept has been particularly shown and described with reference to embodiments thereof, it will be understood that various changes in form and details may be made therein without departing from the spirit and scope of the disclosure.

What is claimed is:

1. An article transfer and storage apparatus comprising:
a case installed in a semiconductor factory and comprising:
a frame, the frame including at least a first shelf plate extending in a first horizontal direction, and
a plurality of storage ports arranged on the first shelf plate, each of the plurality of storage ports configured to accommodate a semiconductor carrier, and
a storage port transport configured to move the storage ports in the first horizontal direction; and
a transfer robot comprising a transport base at a bottom of the transfer robot, the transfer robot configured to place the semiconductor carrier in the case or take out the semiconductor carrier from the case and move the semiconductor carrier.

2. The article transfer and storage apparatus of claim 1, wherein the storage port transport further comprises:
a guide rail fixed to the frame, the guide rail extending in the first horizontal direction, wherein each storage port of the plurality of storage ports is coupled to the guide rail and is configured to move along the guide rail; and
a plurality of electromagnets, each electromagnet configured to provide a driving force to move a corresponding storage port of the plurality of storage ports in the first horizontal direction.

3. The article transfer and storage apparatus of claim 2, wherein each storage port includes a first end and a second end opposite to the first end,
wherein each electromagnet is disposed at the first end of the corresponding storage port, and
wherein the case further comprises a magnetic material disposed at the second end of each storage port of the plurality of storage ports.

4. The article transfer and storage apparatus of claim 3, wherein the case further comprises a damper coupled to one side of the magnetic material disposed at the second end of each storage port.

5. The article transfer and storage apparatus of claim 1, wherein the first shelf plate of the case comprises a spare space corresponding to a size of at least one of the plurality of storage ports.

6. The article transfer and storage apparatus of claim 1, wherein the first shelf plate is one of a plurality of shelf plates spaced apart from each other in a vertical direction.

7. The article transfer and storage apparatus of claim 1, wherein the case further comprises, at a bottom of the case, a plurality of wheels configured to move the case.

8. The article transfer and storage apparatus of claim 1, wherein the case further comprises an identification device configured to recognize an ID of the semiconductor carrier transferred from the transfer robot.

9. The article transfer and storage apparatus of claim 1, wherein the transfer robot comprises a gripper configured to grip the semiconductor carrier and an extendable arm configured to move the gripper in a horizontal direction.

10. The article transfer and storage apparatus of claim 9,
wherein the transfer robot further comprises a rotator configured to rotate the extendable arm in a horizontal direction.

11. The article transfer and storage apparatus of claim 9, wherein the transfer robot further comprises a lift configured to move the extendable arm in a vertical direction.

12. The article transfer and storage apparatus of claim 9, wherein the transfer robot further comprises a transfer shelf configured to support the semiconductor carrier and move a plurality of the semiconductor carriers.

13. The article transfer and storage apparatus of claim 1, wherein the article transfer and storage apparatus comprises a plurality of the transfer robots and each of the plurality of transfer robots operates independently.

14. An article transfer and storage apparatus comprising:
a case installed in a semiconductor factory and comprising:
a frame, the frame including at least a first shelf plate extending in a first horizontal direction, and
a plurality of storage ports arranged on the first shelf plate, each of the plurality of storage ports configured to accommodate a semiconductor carrier, and
a storage port transport configured to move the storage ports in the first horizontal direction; and
a transfer robot comprising a transport base at a bottom of the transfer robot, and the transfer robot configured to place the semiconductor carrier in the case or take out the semiconductor carrier from the case and move the semiconductor carrier,
wherein the first shelf plate of the case includes two rows arranged in a second horizontal direction perpendicular to the first horizontal direction.

15. The article transfer and storage apparatus of claim 14, wherein the storage port transport comprises:
a guide rail fixed to the frame, the guide rail extending in the first horizontal direction;
a rail coupler attached to each of the storage ports and configured to move along the guide rail; and
a port driver configured to provide a driving force to move a corresponding storage port of the plurality of storage ports in the first horizontal direction.

16. The article transfer and storage apparatus of claim 14, wherein the transfer robot further comprises:
a gripper configured to grip the semiconductor carrier,
an extendable arm configured to move the gripper in a horizontal direction,
a rotator configured to rotate the extendable arm in the horizontal direction, and
a lift configured to move the rotator and the extendable arm in a vertical direction.

17. The article transfer and storage apparatus of claim 16, wherein, in the transfer robot, the extendable arm is configured to be extended, and
wherein the gripper is configured to grip the semiconductor carrier placed in a first row of the two rows of the first shelf plate located farther away from the transfer robot in the second horizontal direction than a second row of the two rows of the first shelf plate while the extendable arm is in an extended position.

18. The article transfer and storage apparatus of claim 14, wherein the transfer robot further comprises a transfer shelf configured to support the semiconductor carrier and move a plurality of the semiconductor carriers.

19. The article transfer and storage apparatus of claim 14, wherein the first shelf plate of the case comprises a spare space corresponding to a size of at least one of the plurality of storage ports.

20. An article transfer and storage apparatus comprising:
a case installed in a semiconductor factory and comprising:
a frame, the frame including at least a first shelf plate extending in a first horizontal direction, and
a plurality of storage ports arranged on the first shelf plate, each of the plurality of storage ports configured to accommodate a semiconductor carrier, and
a storage port transport configured to move the storage ports in the first horizontal direction; and
a transfer robot comprising:
a transport base at a bottom of the transfer robot,
a gripper configured to grip the semiconductor carrier,
an extendable arm configured to move the gripper in a horizontal direction,
a lift configured to move the extendable arm in a vertical direction, and
a transfer shelf configured to support the semiconductor carrier, wherein the transfer robot is configured to place the semiconductor carrier in the case or take out the semiconductor carrier from the case and move the semiconductor carrier,
wherein the first shelf plate of the case includes a plurality of floors spaced apart in the vertical direction and further includes two rows arranged in a second horizontal direction perpendicular to the first horizontal direction, each floor of the plurality of floors of the first shelf plate comprising a spare space corresponding to a size of at least one of the plurality of storage ports,
wherein the storage port transport comprises:
a guide rail fixed to the frame, the guide rail extending in the first horizontal direction;
a rail coupler attached to each of the storage ports and configured to move along the guide rail; and
a port driver comprising an electromagnet disposed at a first end of a corresponding storage port of the plurality of storage ports,
a magnetic material disposed at a second end of each storage port of the plurality of storage ports opposite to the first end, and
a damper coupled to one side of the magnetic material disposed at the second end of each storage port,
wherein the port driver is configured to provide a driving force to move the plurality of storage ports in the first horizontal direction,
wherein the case comprises:
a wheel that allows the case to move; and
an identification device configured to recognize an ID of the semiconductor carrier transferred from the transfer robot,
wherein the extendable arm of the transfer robot is configured to extend,
wherein the gripper is configured to grip the semiconductor carrier placed in a first row of the two rows of the first shelf plate located farther away from the transfer robot in the second horizontal direction than a second row of the two rows of the first shelf plate while the extendable arm is in an extended position, and
wherein the article transfer and storage apparatus further comprises a controller configured to move the plurality of storage ports and control the transfer robot to place the semiconductor carrier in the case or to take out the semiconductor carrier from the case.
